(19) United States
(12) Patent Application Publication
(10) Pub. No.: US 2005/0070103 A1
(43) Pub. Date: Mar. 31, 2005

(54) Method and apparatus for endpoint detection during an etch process

(75) Inventors: Shashank C. Deshmukh, San Jose, CA (US); Michael N. Grimbergen, Redwood City, CA (US)

Correspondence Address: MOSER, PATTERSON & SHERIDAN, LLP;APPLIED MATERIALS INC, 595 SHREWSBURY AVE, SUITE 100, SHREWSBURY, NJ, 07702, US

(73) Assignee: Applied Materials, Inc.

(21) Appl. No.: 10/674,631

(22) Filed: Sep. 29, 2003

(51) Int. Cl. H01L 21/302; H01L 21/461

(52) U.S. Cl. 438/689

(57) ABSTRACT

A method and system for endpoint detection during an etch process is disclosed. The endpoint of the etch process is determined using a predetermined metric associated with the direct measurement of the intensity of radiation reflected from the layer being etched at a pre-selected wavelength. By using a direct measurement of the intensity, the layer being etched can have a thickness on the order of the wavelength of the light used for detection. As such, the present invention finds use in etching very thin, high K dielectric materials such as hafnium dioxide, hafnium silicate and the like.

### BACKGROUND OF THE INVENTION

1. Field of the Invention

The present invention generally relates to semiconductor substrate processing systems. More specifically, the present invention relates to optical endpoint detection during semiconductor manufacturing processes.

2. Description of the Related Art

Ultra-large-scale integrated (ULSI) circuits typically include more than one million transistors that are formed on a semiconductor substrate and which cooperate to perform various functions within an electronic device. Such transistors may include complementary metal-oxide-semiconductor (CMOS) field effect transistors.

A CMOS transistor includes a gate structure that is disposed between a source region and a drain region defined in the semiconductor substrate. The gate structure generally comprises a gate electrode formed on a gate dielectric material. The gate electrode controls a flow of charge carriers, beneath the gate dielectric, in a channel region that is formed between the drain and source regions, so as to turn the transistor on or off. The channel, drain and source regions are collectively referred to in the art as a “transistor junction”. There is a constant trend to reduce the dimensions of the transistor junction and, as such, decrease the gate electrode width in order to facilitate an increase in the operation speed of such transistors.

In a CMOS transistor fabrication process, one or more layers of a film stack comprising the gate structure are plasma etched and removed, either partially or in total. In advanced devices, such layers may be very thin, e.g., the gate dielectric layer may have a thickness of about 20 to 100 Angstroms. A requirement during etching thin layers is a prompt termination of the etch process immediately after the etched layer has been removed from the substrate. However, when etching such thin layers (i.e., thicknesses less than 100 Angstroms), conventional endpoint detectors do not operate reliably.

There are two classes of detection systems that are generally used for endpoint detection during a plasma etching process. The first class of detection systems includes laser interferometric detectors. These detectors focus a laser beam on the layer being etched and monitor a phase of the radiation reflected from the layer. As the layer is being etched (removed), the phase of the reflected radiation changes in proportion with a depth for the etch process. In this manner, the detector monitors the etch depth and can cause the etch process to stop upon achieving a predetermined depth. To accurately determine the etch endpoint, the layer being etched should be thicker than a few wavelengths of the light used for endpointing. Dielectric materials that have a dielectric constant greater than four (referred to herein as High K dielectric materials) may have thicknesses that are on the order of the wavelengths of light used in sensing the endpoint; thus making interferometry impractical. Furthermore, to measure minute phase changes, that are required for etching thin layers, the equipment requires repeated re-calibration. Also, as layers become thinner, maintaining the laser focus upon the layer becomes increasingly more difficult.

The second class of detection systems includes optical emission spectrometry (OES) detectors. These detectors detect a change in intensity for one or several wavelengths of the plasma optical emissions related to the etched or underlying layer. Such detectors comprise a plasma optical emission receiver and data acquisition system. The sensitivity of these detectors is reduced when the spectral lines of interest become obscured by the background spectrum. To identify the endpoint of the plasma etch process, the change in the spectrum is typically detected when the etched layer is removed from the substrate. However, as the etched layer becomes thinner, the signal corresponding to the spectral change that occurs when the layer being etched is removed generally becomes small and may be masked by background plasma emissions and missed by the endpoint detection system.

When, during the etch process, the endpoint is missed, there is a risk of overetch or plasma damage to the underlying layers. Therefore, reliable and accurate endpoint detection is critical during etching very thin layers, such as the gate dielectric layer and the like.

Therefore, there is a need in the art for improved endpoint detection when etching a thin material layer formed on a semiconductor wafer.

### SUMMARY OF THE INVENTION

The present invention is a method and system for endpoint detection during an etch process. The endpoint of the etch process is determined using a predetermined metric associated with the direct measurement of the intensity of radiation reflected from the layer being etched at a pre-selected wavelength. By using a direct measurement of the intensity, the layer being etched can have a thickness on the order of the wavelength of the light used for detection. As such, the present invention finds use in etching very thin, high K dielectric materials such as hafnium dioxide, hafnium silicate and the like. In one embodiment, the predetermined metric used to identify the etch endpoint comprises a pre-determined change in the intensity of radiation reflected from the layer being etched at the pre-selected wavelength. In another embodiment, the pre-determined metric is a moment when an intensity for the reflected radiation at the pre-selected wavelength stops changing as a function of time. In one application, the invention is used to determine endpoint detection during a gate dielectric layer etch process for fabricating a field effect transistor.

### BRIEF DESCRIPTION OF THE DRAWINGS

The teachings of the present invention can be readily understood by considering the following detailed description in conjunction with the accompanying drawings, in which:

FIG. 1 depicts a flow diagram of a method for providing endpoint detection during an etch process in accordance with the present invention;

FIGS. 2A-2D depict schematic, cross-sectional views of a substrate having a layer etched using the method depicted in FIG. 1;

FIG. 3 depicts an expanded cross-sectional view of the film stack of FIG. 2B;

FIGS. 4A-4C depict a series of graphs showing a change in intensity for reflected radiation during the etch process;

FIG. 5 depicts a graph showing a change in intensity for reflected radiation during the etch process at one selected wavelength; and

FIG. 6 depicts a schematic view of an exemplary etch reactor including an endpoint detection system in accordance with the present invention.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method and system for endpoint detection during an etch process. In one embodiment, a thin material layer (e.g., layer having a thickness of about 20 to 100 Angstroms) formed on a semiconductor substrate, such as a silicon (Si) wafer is etched. The invention finds specific use when the thickness of the layer is on the order of the wavelength of the light used for endpoint detection. The endpoint of the etch process is determined using a predetermined metric associated with the direct measurement of the intensity of radiation reflected from the layer being etched at a pre-selected wavelength. In one embodiment, the predetermined metric comprises a pre-determined change in the intensity of radiation reflected from the layer being etched at the pre-selected wavelength. In another embodiment, the pre-determined metric is a moment when an intensity for the reflected radiation at the pre-selected wavelength stops changing as a function of time. In one application, the invention is used to provide endpoint detection during a gate dielectric layer etch process for fabricating a field effect transistor.

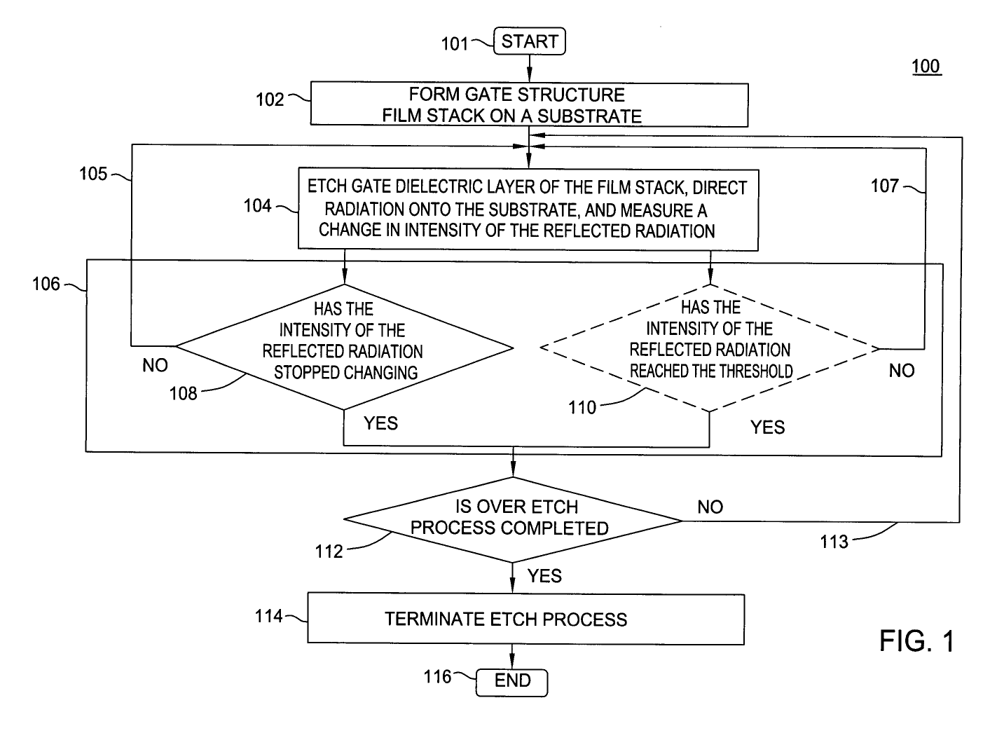

FIG. 1 depicts a flow diagram of a method for determining the endpoint of an etch process in accordance with the present invention as sequence 100. In one illustrative embodiment, the sequence 100 comprises processes that are performed when etching a thin gate dielectric layer of a gate structure of a field effect transistor, such as a complementary metal-oxide-semiconductor (CMOS) transistor and the like.

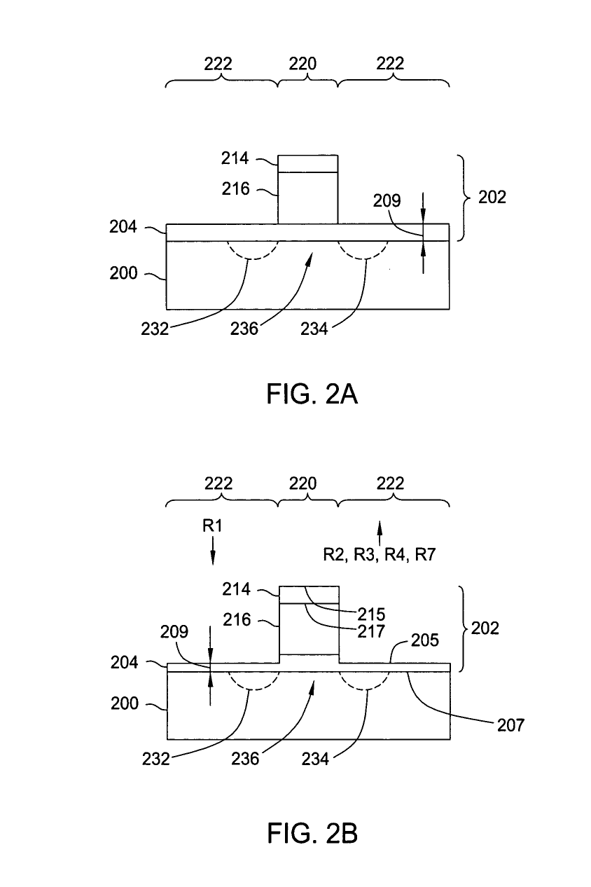

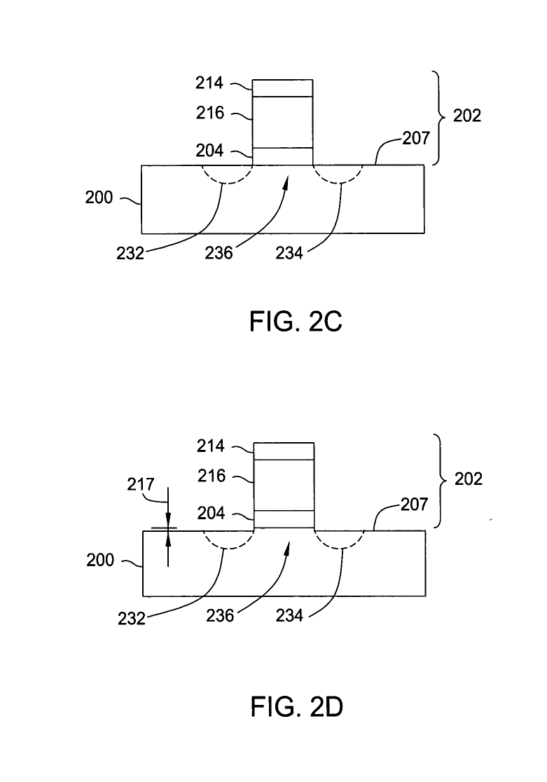

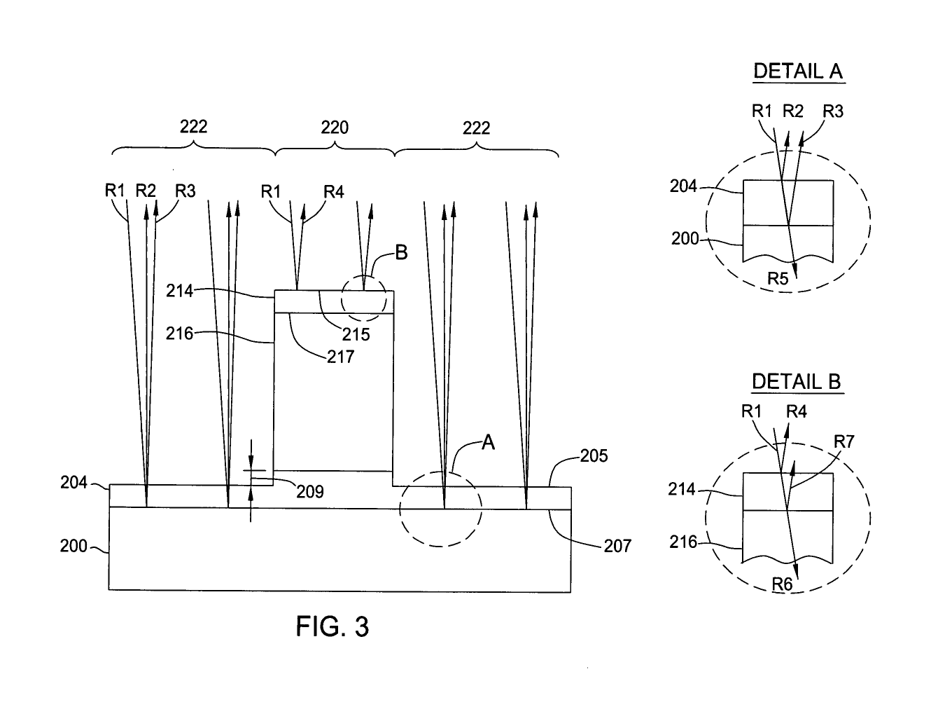

FIGS. 2A-2D, depict a sequence of schematic, cross-sectional views of a substrate having a gate dielectric layer being etched in accordance with the sequence 100 of FIG. 1. FIG. 3 depicts an expanded cross-sectional view of FIG. 2B. The cross-sectional views in FIGS. 2A-2D relate to specific phases of the etch process. The images in FIGS. 2A-2D and FIG. 3 are not depicted to scale and are simplified for illustrative purposes. For best understanding of the invention, the reader should refer simultaneously to FIG. 1, FIGS. 2A-2D, and FIG. 3.

The sequence 100 starts at step 101 and proceeds to step 102. At step 102, a film stack 202 for a gate structure of a CMOS transistor is formed on a substrate 200 (FIG. 2A). The substrate 200, e.g., a silicon wafer, includes regions 232 and 234 where doped source regions (wells) 232 and doped drain regions (wells) 234 that are separated by a channel region 236 will be formed. Usually the dopants are implanted after the gate structure is formed such that the gate structure is used as a mask for the dopants implantation process. These regions 232 and 234 are indicated by dashed lines. The terms “substrate” and “wafer” herein are used interchangeably.

The film stack 202 includes a gate electrode 216, a gate dielectric layer 204, and an etch mask 214. In one illustrative embodiment, the gate electrode 216 is formed from doped polysilicon (Si) to a thickness of about 1000 to 2000 Angstroms, and the gate dielectric layer 204 is formed of hafnium dioxide (HfO₂) to a thickness 209 of about 20 to 100 Angstroms. Alternatively, the gate dielectric material may be formed of hafnium silicate (HfSiO₂), and the like. The etch mask 214 generally may be formed from silicon oxynitride (SiON), silicon dioxide (SiO₂), and the like. The etch mask 214 is disposed on the gate electrode 216 and, as such, protects a region 220 (gate electrode) and exposes adjacent regions 222.

The number and composition of the layers formed on the substrate 200 are shown and discussed for illustrative purposes only and are not to be considered as limiting. In other embodiments, the film stack 202 may comprise other layers or layers formed from different materials or to a different thickness.

The gate dielectric layer 204 may be provided using any vacuum deposition technique, such as atomic layer deposition (ALD), chemical vapor deposition (CVD), plasma enhanced CVD (PECVD), and the like. The processes used to form the gate electrode 216 and etch mask 214 are described, e.g., in commonly assigned U.S. patent application Ser. No. 10/245,130, filed Sep. 16, 2002 and Ser. No. 10/338,251, filed Jan. 6, 2003, which are incorporated herein by reference.

At step 104, the gate dielectric layer 204 comprising hafnium dioxide (HfO₂) is etched and removed in the unprotected regions 222 (FIG. 2B). In one embodiment, step 104 uses a gas mixture including a halogen gas such as chlorine (Cl₂) and the like, a hydrocarbon gas such as methane (CH₄), ethylene (C₂H₆), propane (C₃H₈), butane (C₄H₁₀), and the like, as well as an optional reducing gas, such as carbon monoxide (CO). The etch process provides high etch selectivity to the gate dielectric layer 204 (e.g., layer of hafnium dioxide (HfO₂), hafnium silicate (HfSiO₂), and the like) over polysilicon (gate electrode 216) and silicon (wafer 200), as well as over silicon oxynitride (SiON) or silicon dioxide (SiO₂) (mask 214). Such etch process is described, e.g., in commonly assigned U.S. patent application Ser. No. 10/194,566, filed Jul. 12, 2002, which is incorporated herein by reference.

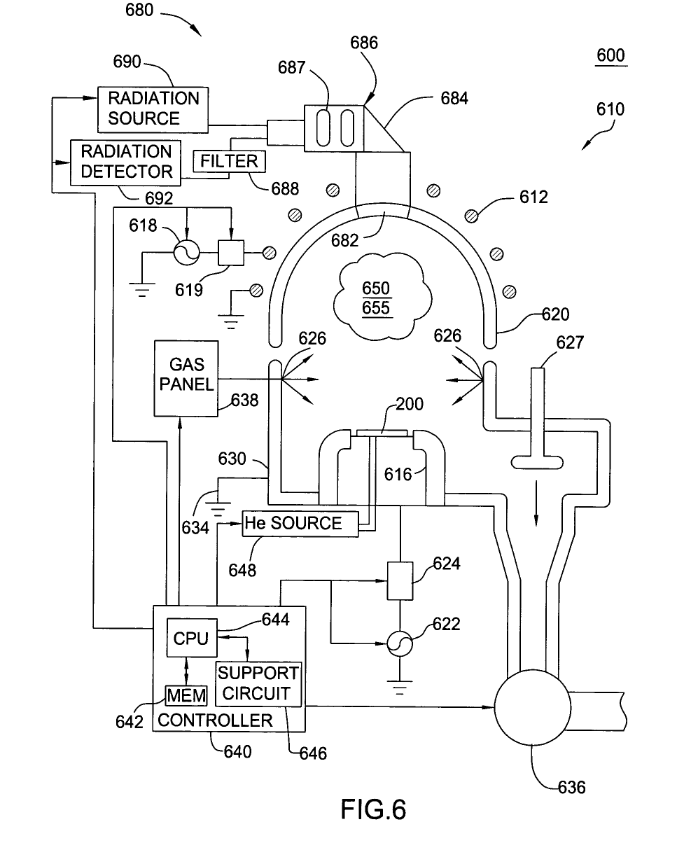

During step 104, an endpoint of the etch process is determined by an endpoint detection system (discussed below with reference to FIG. 6) that monitors a difference in reflectivity for the etched layer as compared to a layer underlying the etched layer. Further, the endpoint detection system utilizes the dependence of the reflectivity based on a thickness for the etched layer as well as the wavelength and angle of incidence for the radiation that is used to illuminate the substrate. More specifically, the endpoint detection system illuminates a region on the substrate using a broadband source of radiation and then directly measures a change in intensity of the reflected radiation at one or more selected wavelengths. Since the thickness of the layer being etched is on the order of the wavelength of the light used for endpointing, an interferometer-type endpoint system is impractical.

Step 104 may be performed, for example, using the Decoupled Plasma Source-High Temperature (DPS-HT) etch reactor of the CENTURA® processing system available from Applied Materials, Inc. of Santa Clara, Calif.

Referring to FIGS. 3 and 6, during the etch process, the substrate is monitored using an endpoint detection system 680 that comprises a broadband radiation source and a radiation detector. The substrate 200 is illuminated using, e.g., a broadband radiation source 690 that produces radiation having wavelengths that are on the order of the thickness of the layer being etched, e.g., within a range from about 200 to 800 nm, i.e., in ultra-violet and deep ultra-violet ranges. The thickness of the layer being etched may be 5 to 300 Angstroms.

To increase accuracy of the endpoint detection system 680 and, specifically, the accuracy of a radiation detector 692 of the system, the intensity of the radiation produced by the radiation source 690 (i.e., intensity of incident radiation) may be modulated and/or pulsed. A frequency of such modulation is generally at least 1 Hz, while a duty cycle of pulses for the radiation is about 0.0001 to 50%.

The incident radiation (rays R1) is directed substantially perpendicular to the substrate 200. As such, the incident radiation is substantially perpendicular to a surface 205 of the gate dielectric layer 204, surface 207 of the substrate 200, surface 215 of the etch mask 214, and surface 217 of the polisilicon gate electrode 216. The incident radiation is partially reflected back from the surfaces 205, 207, 215 and 217 and partially propagates into the gate dielectric layer 204 (through the surface 205) and the etch mask 214 (through the surface 215).

Generally, such incident radiation illuminates a region (e.g., center region) on the substrate 200 that is large enough to comprise several features being etched, such as film stacks 202, e.g., a region having a minimal width (or diameter) of about 5 to 15 mm. In alternative embodiments, the illuminated region may be either greater or smaller and, as such, the size or shape of the illuminated region should not limit the scope of the invention. More specifically, the illuminated region should encompass at least a portion of the region 222 of at least one film stack 202.

Since the angles of incidence and reflection are equal to one another, a reflected portion (rays R2, R3, and R4) of the incident radiation (i.e., rays R1) propagates in the direction that is also substantially perpendicular to the substrate 200. As such, the radiation that is reflected from the substrate 200 returns, through the window 682, to an optical assembly 686. In the optical assembly 684, such radiation (i.e., rays R2, R3, and R4) is collected and then guided to a filter 688 and, through the filter 688, to the radiation detector 692 (discussed above in reference to FIG. 6 above). Since only the first order reflections from the surfaces 205, 207, 215, and 217 are of practical significance, high order reflections from such surfaces may not be considered as a limiting factor. Similarly, refraction of the incident and reflected radiation that is caused by materials of the layers comprising the film stack 202 also may not be considered as a limiting factor.

A portion of the incident radiation that propagates into the etch mask 214 is further partially reflected back from the surface 217 (rays R7) and partially propagates (rays R6) into the gate electrode 216, where such radiation is absorbed by the material (i.e., polysilicon) of the gate electrode. As discussed above, the etch process of step 104 provides high etch selectivity to the material (e.g., silicon oxynitride (SiON), silicon dioxide (SiO₂) and the like) of the etch mask 214. As such, during the etch process, a change in intensity for the radiation that is reflected from the etch mask 214 is relatively small or undetectable. Further, an area of the surface 215 is generally substantially smaller than the area of the surface 205. Therefore, a total intensity of the radiation reflected from the surfaces 215 and 217 is substantially smaller than the radiation reflected from the surfaces 205 and 207. As such, during the etch process, the intensity for the radiation (i.e., rays R4 and R7) reflected from the regions 220 practically does not change and represents a small portion of the total radiation (i.e., a sum of rays R2, R3, R4, and R7) that is reflected from the substrate 200.

The portion of the incident radiation that propagates into the gate dielectric layer 204 is partially reflected back from the surface 205 (rays R2) and partially propagates further (rays R5) into the gate dielectric layer 204. In the gate dielectric layer 204, the penetrated radiation is mostly reflected back (ray R3) from the surface 207, while a small portion (ray R5) of the radiation propagates into the substrate 200, where such radiation is absorbed by the material (i.e., silicon) of the substrate.

The reflectivity for the silicon surface 207 is substantially greater than the reflectivity of the gate dielectric material (i.e., hafnium dioxide (HfO₂) or hafnium silicate (HfSiO₂)) of surface 205. Further, during the etch process, as the thickness 209 of the gate dielectric layer 204 decreases, the absorption of the incident radiation (i.e., rays R1) in the layer 204 also decreases. As such, during the etch process, a portion of the radiation (i.e., a sum of rays R2 and R3) that is the reflected from the regions 222 is a function of the thickness 209 of the gate dielectric layer 204 and such portion gradually increases as the etch process continues to etch (remove) the material of the layer 204.

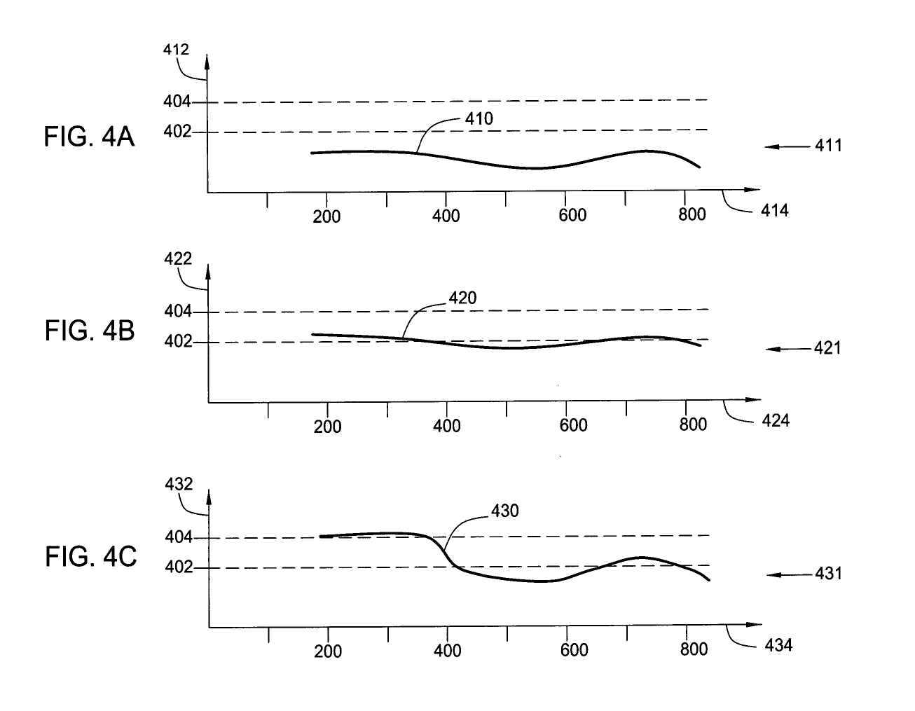

FIGS. 4A-4C depict a series of graphs showing a change of intensity for the radiation reflected from the substrate 200 during various phases of the etch process. Graph 411 depicts the intensity (y-axis 412) of radiation that is reflected from the substrate 200 versus wavelength (x-axis 414) prior to the beginning of the etch process. Graph 421 depicts the intensity (y-axis 422) of the radiation that is reflected from the substrate 200 versus wavelength (x-axis 424) during an intermediate phase of the etch process. Graph 431 depicts the intensity (y-axis 432) of the radiation that is reflected from the substrate 200 versus wavelength (x-axis 434) upon completion the etch process (i.e., when the gate dielectric layer 204 is removed in the regions 222). Empirically defined thresholds 402 and 404 relate to the maximum values of the intensity prior to the etch process and to the minimum intensity upon completion of the etch process, respectively.

Referring to FIGS. 4A-4C, changes in the intensity of the radiation reflected from the substrate 200 may vary from wavelength to wavelength. Furthermore, the direction for such change (i.e., decreasing or increasing of the intensity) may be different within the range (e.g., from about 200 to 800 nm) of wavelengths produced by the radiation source 690 (FIG. 6). As such, monitoring the reflected radiation at one or more wavelengths that, during the etch process, demonstrate a big change in the intensity, provides accurate detection of an endpoint for the etch process. Generally, larger changes for the intensity are observed at short wavelengths rather than at long wavelengths. Correspondingly, in one embodiment of the endpoint detection system 680 (FIG. 6), the filter 688 transmits, to the radiation detector 692, reflected radiation having short wavelengths (e.g., with a center wavelength about 200 to 350 nm), and suppresses (i.e., filters) radiation having long wavelengths.

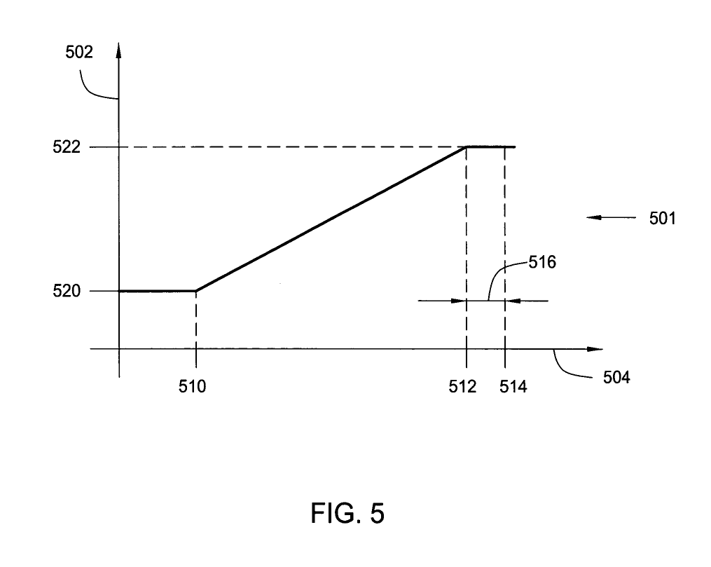

FIG. 5 depicts a graph showing a change in intensity for reflected radiation during the etch process at one wavelength, e.g., at one short wavelength that, during the etch process, demonstrates a big change of the intensity. More specifically, graph 501 shows an exemplary output signal (y-axis 502) for the radiation detector 692 plotted as a function of time (x-axis 504) during the etch process.

The etch process begins at a moment 510. At the moment 510, the output signal has a value 520 that corresponds to intensity, at the selected wavelength, for the radiation that is reflected from the substrate 200. The output signal gradually changes as the etch process continues (e.g., in the depicted embodiment, the output signal arbitrarily increases). For example, the gate dielectric layer 204 is removed in the unprotected regions 222 (discussed above with reference to FIG. 2C) during the etch process. At the moment 512, the output signal stops changing with time and reaches a value (threshold) 522.

In one embodiment, the endpoint detection system 680 defines an end of the etch process as a moment when the output signal stops changing with time, i.e., moment 512. In an alternative embodiment, the endpoint detection system 680 defines the end of etch process as the moment when a value of the output signal becomes equal to the threshold 522. In a further embodiment, the etch process may continue for a controlled overetch period 516 till a moment 514. Such overetch period is generally used to remove any traces of the etched layer (e.g., gate dielectric layer 204) in the unprotected regions 222. Generally, the overetch process also removes from the substrate 200 a film of silicon having a thickness 217 (discussed with reference to FIG. 2D) of about 500 Angstroms or less.

At step 106, the method 100 queries whether the dielectric layer 204 has been removed from the wafer 200 in the regions 222. Step 106 uses information that is contained in the output signal of the radiation detector 692 to detect the endpoint of the etch process.

In one embodiment, using a decision procedure 108, step 106 determines whether the intensity of the radiation reflected from the substrate 200 has stopped changing after a period of gradual increasing since the beginning of the etch process. In an alternative embodiment (shown in phantom), using a decision procedure 110, step 106 determines whether the intensity has reached a predetermined level, e.g., threshold 522 (discussed above with reference to FIG. 5 above).

If the query of the procedure 108 or the query of the procedure 110 is negatively answered, the sequence 100 proceeds to step 104 to continue the etch process, as illustratively shown using links 105 and 107, respectively. If the query of the procedure 108 or the query of the procedure 110 is affirmatively answered (corresponding to FIG. 2C), the sequence 100 proceeds to step 112.

At step 112, the sequence 100 queries whether the overetch process has been completed. Generally, step 112 uses control of the process time that is specified for the overetch process. In some applications, the overetch process is not needed, as such, step 112 is considered optional. If the query of step 112 is negatively answered, the sequence 100 proceeds to step 104 to continue the etch process, as illustratively shown using a link 113.

If the query of step 112 is affirmatively answered (corresponds to FIG. 2D), the sequence 100 proceeds to step 114. At step 114, the sequence 100 ends.

FIG. 6 depicts a schematic diagram of an exemplary DPS-HT etch reactor 600 suitable for performing portions of the present invention. The DPS-HT etch reactor is available from Applied Materials, Inc. of Santa Clara, Calif. The reactor 600 comprises a process chamber 610 having a wafer support pedestal 616 within a conductive body (wall) 630, an endpoint detection system 680, and a controller 640.

The support pedestal (cathode) 616 is coupled, through a first matching network 624, to a biasing power source 622. The biasing source 622 generally is a source of up to 500 W at a frequency of approximately 13.56 MHz, which is capable of producing either continuous or pulsed power. In other embodiments, the source 622 may be a DC or pulsed DC source. The chamber 610 is supplied with a dome-shaped dielectric lid (ceiling) 620. Other modifications of the chamber 610 may have other types of ceilings, e.g., a substantially flat ceiling. Above the ceiling 620 is disposed an inductive coil antenna 612. The antenna 612 is coupled, through a second matching network 619, to a plasma power source 618. The plasma source 618 typically is capable of producing up to 3000 W at a tunable frequency in a range from 50 kHz to 13.56 MHz. Typically, the wall 630 is coupled to an electrical ground 634.

The endpoint detection system 680 generally comprises a radiation source 690, a radiation detector 692, a filter 688, and an optical assembly 686. The optical assembly 686 is disposed over a window 682 formed in the ceiling 620. The window 682 may be fabricated from quartz, sapphire, or other material that is transparent to the radiation produced by the radiation source 690.

The radiation source 690 is generally a source of radiation having a spectrum (wavelengths) within a range from about 200 to 800 nm. Such radiation source 690 may comprise, e.g., a mercury (Hg), xenon (Xe) or Hg-Xe lamp, tungsten-halogen lamp, light emitting diode (LED), and the like.

The filter 688 selectively transmits the radiation having desired wavelengths to the radiation detector 692. The filter 688 may comprise a tuned stack of thin films that are formed on a transparent substrate, a diffraction grating, and the like. In the embodiment depicted, the filter 688 is a stand-alone apparatus. Alternatively, the filter 688 may be a part of the radiation detector 692 or optical assembly 686.

The radiation detector 692 provides an electrical output signal that is related to the intensity of the radiation reflected, at one or several selected wavelengths, by the substrate 200. The radiation detector 692 may comprise a photo-multiplier, a charge coupled device (CCD), a phototransistor, and the like.

The optical assembly 686 generally comprises passive optical components, e.g., at least one lens 687 and/or mirror 684, beam splitters, and the like. Such optical components guide and focus the radiation from the radiation source 690 onto the substrate 200, as well as collect the radiation reflected from the substrate 200 and guide the radiation to the filter 688. Optical interfaces between the optical assembly 686, radiation source 690, filter 688, and radiation detector 692 are provided using fiber-optic cables. In one illustrative embodiment, the endpoint detection system 680 comprises an EyeD™ module available from Applied Materials of Santa Clara, Calif.

In an alternative embodiment, the radiation source 690 and filter 688 may be directly mounted on the ceiling 620 and, as such, the optical assembly 686 is considered optional.

A controller 640 comprises a central processing unit (CPU) 644, a memory 642, and support circuits 646 for the CPU 644 and facilitates control of the components of the DPS etch process chamber 610 and, as such, of the etch process, as discussed below in further detail.

In operation, the wafer 200 is placed on the pedestal 616 and process gases are supplied from a gas panel 638 through entry ports 626 to form a gaseous mixture 650. The gaseous mixture 650 is ignited into a plasma 655 in the chamber 610 by applying power from the plasma and bias sources 618, 622 to the antenna 612 and the pedestal 616, respectively. The pressure within the interior of the chamber 610 is controlled using a throttle valve 627 and a vacuum pump 636. The temperature of the chamber wall 630 is controlled using liquid-containing conduits (not shown) that run through the wall 630.

The temperature of the wafer 200 is controlled by stabilizing a temperature of the support pedestal 616. In one embodiment, helium gas from a gas source 648 is provided via a gas conduit 649 to channels formed in the pedestal surface beneath the wafer 200. The helium gas is used to facilitate heat transfer between the pedestal 616 and the wafer 200. During the processing, the pedestal 616 may be heated by a resistive heater (not shown) within the pedestal to a steady state temperature and then the helium gas facilitates uniform heating of the wafer 200. Using such thermal control, the wafer 200 is maintained at a temperature of between 200 and 350 degrees Celsius.

Those skilled in the art will understand that other forms of etch chambers may be used to practice the invention, including chambers with remote plasma sources, microwave plasma chambers, electron cyclotron resonance (ECR) plasma chambers, and the like.

To facilitate control of the process chamber 610 as described above, the controller 640 may be one of any form of general-purpose computer processor that can be used in an industrial setting for controlling various chambers and sub-processors. The memory 642, or computer-readable medium, of the CPU 644 may be one or more of readily available memory such as random access memory (RAM), read only memory (ROM), floppy disk, hard disk, or any other form of digital storage, local or remote. The support circuits 646 are coupled to the CPU 644 for supporting the processor in a conventional manner. These circuits include cache, power supplies, clock circuits, input/output circuitry and subsystems, and the like. The inventive method is generally stored in the memory 642 as a software routine. The software routine may also be stored and/or executed by a second CPU (not shown) that is remotely located from the hardware being controlled by the CPU 644.

The invention may be practiced using other semiconductor wafer processing systems wherein the processing parameters may be adjusted to achieve acceptable characteristics by those skilled in the arts by utilizing the teachings disclosed herein without departing from the spirit of the invention.

Although the forgoing discussion referred to fabrication of a gate structure of the field effect transistor, fabrication of the other devices and structures that are used in the integrated circuits can benefit from the invention.

While foregoing is directed to the illustrative embodiment of the present invention, other and further embodiments of the invention may be devised without departing from the basic scope thereof, and the scope thereof is determined by the claims that follow.

1. A method for determining the endpoint of an etch process, comprising:
(a) providing a substrate comprising a material layer having a thickness;
(b) etching the material layer on the substrate;
(c) directing radiation onto the substrate as the material layer is etched, where the radiation has a wavelength that is on the order of the thickness of the material layer;
(d) measuring a change in intensity for radiation reflected from the substrate at a pre-selected wavelength as the material layer is etched; and
(e) terminating the etch step upon measuring a predetermined metric for the change in intensity of radiation reflected from the substrate at the pre-selected wavelength.

2. The method of claim 1 wherein the radiation has a wavelength within a range from about 200 to 800 nm onto the substrate.

3. The method of claim 1 wherein the thickness of the material layer is 5 to 300 Angstroms.

4. The method of claim 1 wherein the thickness of the material layer is less than or equal to the wavelength of the radiation.

5. The method of claim 1 wherein step (c) comprises:
directing the radiation substantially perpendicular to the material layer; and
modulating the intensity of the directed radiation.

6. The method of claim 1 wherein step (d) comprises:
filtering wavelengths other than the pre-selected wavelength.

7. The method of claim 1 wherein the predetermined metric is associated with measuring a predetermined change in intensity for the reflected radiation at the pre-selected wavelength.

8. The method of claim 1 wherein the predetermined metric is associated with measuring a substantially constant intensity for the reflected radiation as a function of time at the pre-selected wavelength.

9. The method of claim 7 wherein measuring the predetermined change of intensity for the reflected radiation is associated with removal of the material layer from the substrate.

10. The method of claim 8 wherein measuring the substantially constant intensity for the reflected radiation as a function of time is associated with removal of the material layer from the substrate.

11. A method for determining the endpoint for etching a gate dielectric layer of a transistor, comprising:
(a) providing a substrate comprising a gate dielectric layer having a thickness;
(b) etching the gate dielectric layer on the substrate;
(c) directing radiation onto the substrate as the gate dielectric layer is etched, where the radiation has a wavelength that is on the order of the thickness of the gate dielectric layer;
(d) measuring a change in intensity for radiation reflected from the substrate at a pre-selected wavelength as the gate dielectric layer is etched; and
(e) terminating the etch step upon measuring a predetermined metric for the change in intensity of radiation reflected from the substrate at the pre-selected wavelength.

12. The method of claim 11 wherein the thickness of the gate dielectric layer is less than or equal to the wavelength of the radiation.

13. The method of claim 11 wherein the gate dielectric layer comprises at least one film of hafnium dioxide (HfO₂) and hafnium silicate (HfSiO₂).

14. The method of claim 11 wherein the thickness of the gate dielectric layer is about 5 to 300 Angstroms.

15. The method of claim 11 wherein step (c) comprises:
directing radiation having wavelengths within a range from about 200 to 800 nm onto the substrate.

16. The method of claim 11 wherein step (c) comprises:
directing the radiation substantially perpendicular to the gate dielectric layer; and
modulating the intensity of the directed radiation.

17. The method of claim 11 wherein step (d) comprises:
filtering wavelengths other than the pre-selected wavelength.

18. The method of claim 11 wherein the predetermined metric is associated with measuring a predetermined change in intensity for the reflected radiation at the pre-selected wavelength.

19. The method of claim 11 wherein the predetermined metric is associated with measuring a substantially constant intensity for the reflected radiation as a function of time at the pre-selected wavelength.

20. The method of claim 18 wherein measuring the predetermined change of intensity for the reflected radiation is associated with removal of the gate dielectric layer from the substrate.

21. The method of claim 20 wherein measuring the substantially constant intensity for the reflected radiation as a function of time is associated with removal of the gate dielectric layer from the substrate.

22. An apparatus for determining the endpoint of an etch process, comprising:
a source of radiation to illuminate a substrate disposed on a substrate pedestal during the etch process, where the radiation has a wavelength that is on the order of a thickness of a material layer on the substrate that is to be etched;
a detector to receive radiation reflected from the material layer at a pre-selected wavelength during the etch process; and
a means for measuring an intensity for the reflected radiation at the pre-selected wavelength, wherein the etch process is terminated upon measurement of a predetermined metric for a change in intensity of radiation reflected from the material layer at the pre-selected wavelength.

23. The apparatus of claim 22 wherein the source radiates and the detector receives radiation having wavelengths within a range from about 200 to 800 nm.

24. The apparatus of claim 22 wherein the thickness of the material layer is 5 to 300 Angstroms.

25. The apparatus of claim 22 wherein the thickness of the material layer is less than or equal to the wavelength of the radiation.

26. The apparatus of claim 22 wherein the source directs the radiation substantially perpendicular to the substrate.

27. The apparatus of claim 22 wherein the means filters wavelengths other than the pre-selected wavelength.

28. The apparatus of claim 22 wherein the predetermined metric is associated with measuring a predetermined change in intensity for the reflected radiation at the pre-selected wavelength.

29. The apparatus of claim 22 wherein the predetermined metric is associated with measuring a substantially constant intensity for the reflected radiation as a function of time at the pre-selected wavelength.

30. The apparatus of claim 28 wherein measuring the predetermined change of intensity for the reflected radiation is associated with removal of the material layer from the substrate.

31. The apparatus of claim 29 wherein measuring the substantially constant intensity for the reflected radiation as a function of time is associated with removal of the material layer from the substrate.

32. A computer-readable medium containing software that, when executed by a computer, causes a processing system to detect an endpoint of an etch process using a method, comprising:
(a) providing a substrate comprising a material layer having a thickness;
(b) etching the material layer on the substrate;
(c) directing radiation onto the substrate as the material layer is etched, where the radiation has a wavelength that is on the order of the thickness of the material layer;
(d) measuring a change in intensity for radiation reflected from the substrate at a pre-selected wavelength as the material layer is etched; and
(e) terminating the etch step upon measuring a predetermined metric for the change in intensity of radiation reflected from the substrate at the pre-selected wavelength.

33. The computer-readable medium of claim 32 wherein step (c) comprises:
directing radiation having wavelengths within a range from about 200 to 800 nm onto the substrate.

34. The computer-readable medium of claim 32 wherein the thickness of the material layer is 5 to 300 Angstroms.

35. The computer-readable medium of claim 32 wherein the thickness of the material layer is less than or equal to the wavelength of the radiation.

36. The computer-readable medium of claim 32 wherein step (c) comprises:
directing the radiation substantially perpendicular to the material layer; and
modulating the intensity of the directed radiation.

37. The computer-readable medium of claim 32 wherein step (d) comprises:
filtering wavelengths other than the pre-selected wavelength.

38. The computer-readable medium of claim 32 wherein the predetermined metric is associated with measuring a predetermined change in intensity for the reflected radiation at the pre-selected wavelength.

39. The computer-readable medium of claim 32 wherein the predetermined metric is associated with measuring a substantially constant intensity for the reflected radiation as a function of time at the pre-selected wavelength.

40. The computer-readable medium of claim 38 wherein measuring the predetermined change of intensity for the reflected radiation is associated with removal of the material layer from the substrate.

41. The computer-readable medium of claim 39 wherein measuring the substantially constant intensity for the reflected radiation as a function of time is associated with removal of the material layer from the substrate.
